(19) United States
(12) Patent Application Publication
(10) Pub. No.: US 2021/0343982 A1
(43) Pub. Date: Nov. 4, 2021

(54) ORGANIC LIGHT-EMITTING DIODE (OLED) DISPLAY PANEL AND OLED DISPLAY PANEL MANUFACTURING METHOD

(71) Applicant: Wuhan China Star Optoelectronics Semiconductor Display Technology Co., Ltd., Wuhan, Hubei (CN)

(72) Inventors: Bo Wu, Wuhan, Hubei (CN); Fenghao Cai, Wuhan, Hubei (CN); Chunguang Zhu, Wuhan, Hubei (CN); Xin Ge, Wuhan, Hubei (CN); Tengfei Liu, Wuhan, Hubei (CN)

(21) Appl. No.: 16/604,361

(22) PCT Filed: Oct. 9, 2018
(86) PCT No.: PCT/CN2018/109386

§ 371 Date: Oct. 10, 2019

(30) Foreign Application Priority Data
Sep. 17, 2018 (CN) 201811081518.7

(51) Int. Cl. H01L 51/52; H01L 51/56

(52) U.S. Cl. CPC H01L 51/5253; H01L 27/3276; H01L 51/56

(57) ABSTRACT

An organic light-emitting diode (OLED) display panel and a manufacturing method thereof are provided. the OLED display panel includes: a substrate, an OLED layer and an encapsulating portion. The substrate includes a displaying region, and a non-displaying region located on an outside of the displaying region. The OLED layer is disposed in the displaying region of the substrate. The encapsulating portion is disposed above the OLED layer. The encapsulating portion includes an organic layer and at least one blocking wall surrounding the organic layer. The organic layer is located in a blocking space of the blocking wall.

### FIELD OF INVENTION

The present invention relates to fields of displays, especially to an organic light-emitting diode (OLED) display panel and a OLED display panel manufacturing method.

### BACKGROUND OF INVENTION

Organic Light-Emitting Diode (OLED) displaying technology is different from conventional liquid crystal display technology. An OLED display needs no backlight, is self-luminous and employs extremely thin organic material coatings and glass substrates. When there is current, these organic materials illuminate, and the display can be made lighter and thinner with a wider viewing angle, and can save significant power energy.

An encapsulating portion of an OLED display panel usually employs a stacked structure disposed sequentially with an inorganic layer, an organic layer, and an inorganic layer. The structure of the inorganic layer is mainly configured to prevent penetration of water and oxygen. The structure of the organic layer is configured to improve stress between layers and cover particles. During leveling of an organic solution, to match a film-forming region of two stacked inorganic films, it is necessary to dispose and level the organic solution on a predetermined position to form a leveled film. When the organic solution is leveled, the solution overflows and spreads, the accuracy of the OLED display panel is reduced and the OLED display panel is less resistant to water and oxygen.

### SUMMARY OF INVENTION

The present invention provides an organic light-emitting diode (OLED) display panel and an OLED display panel manufacturing method to solve an issue that during a manufacturing process of an encapsulating portion of a conventional OLED display panel, because an organic solution overflows and spreads when is leveled, the accuracy of the OLED display panel is reduced and the OLED display panel is less resistant to water oxygen.

To achieve the above objective, the present invention provides technical solutions as follows:

According to an aspect of the present invention, an OLED display panel is provided and comprises:

a substrate comprising a displaying region and a non-displaying region located outside the displaying region;

an OLED layer disposed in the displaying region of the substrate;

an encapsulating portion disposed above the OLED layer, and the encapsulating portion comprising an organic layer and at least one blocking wall surrounding the organic layer, wherein a height of the blocking wall is greater than 2 microns and is less than 4 microns; and

wherein the blocking wall is disposed in the non-displaying region of the substrate and is located at an edge of the non-displaying region, and the organic layer is located in a blocking space of the blocking wall.

According to an embodiment of the present invention, a cross section of the blocking wall is an inverted trapezoid structure.

According to an embodiment of the present invention, a material for forming the blocking wall comprises polystyrene (PS).

According to an embodiment of the present invention, the encapsulating portion further comprises a first inorganic layer and a second inorganic layer;

the first inorganic layer covers the OLED layer and extends to the non-displaying region of the substrate;

the blocking wall is formed on the first inorganic layer;

the organic layer is formed in the blocking space of the blocking wall; and

the second inorganic layer covers the organic layer and the blocking wall.

According to an embodiment of the present invention, the second inorganic layer covers a side of the blocking wall and contacts the first inorganic layer.

According to an embodiment of the present invention, a thin film transistor array is disposed in the displaying region and is arranged evenly, and a driver circuit and metal wires are disposed in the non-displaying region.

According to an embodiment of the present invention, the OLED display panel further comprises a polarizer and a cover plate disposed on the encapsulating portion.

According to another aspect of the present invention, an OLED display panel is provided and comprises:

a substrate comprising a displaying region and a non-displaying region located outside the displaying region;

an OLED layer disposed in the displaying region of the substrate;

an encapsulating portion disposed above the OLED layer, and the encapsulating portion comprising an organic layer and at least one blocking wall surrounding the organic layer;

wherein the blocking wall is disposed in the non-displaying region of the substrate and is located at an edge of the non-displaying region, and the organic layer is located in a blocking space of the blocking wall.

According to an embodiment of the present invention, a cross section of the blocking wall is an inverted trapezoid structure.

According to an embodiment of the present invention, a material for forming the blocking wall comprises polystyrene (PS).

According to an embodiment of the present invention, the encapsulating portion further comprises a first inorganic layer and a second inorganic layer;

the first inorganic layer covers the OLED layer and extends to the non-displaying region of the substrate;

the blocking wall is formed on the first inorganic layer;

the organic layer is formed in the blocking space of the blocking wall;

the second inorganic layer covers the organic layer and the blocking wall.

According to an embodiment of the present invention, the second inorganic layer covers a side of the blocking wall and contacts the first inorganic layer.

According to an embodiment of the present invention, a thin film transistor array is disposed in the displaying region and is arranged evenly, and a driver circuit and metal wires are disposed in the non-displaying region.

According to an embodiment of the present invention, the OLED display panel further comprising a polarizer and a cover plate disposed on the encapsulating portion.

According to still another aspect of the present invention, [symbol] an OLED display panel manufacturing method is provided and comprises:

step S10, providing a substrate, wherein the substrate comprises a displaying region and a non-displaying region located outside the displaying region;

step S20, forming an OLED layer on the substrate, wherein the OLED layer is disposed in the displaying region; and

step S30, forming a first inorganic layer located above the substrate and covering the OLED layer, forming at least one blocking wall on the first inorganic layer, forming an organic layer in a blocking space of the blocking wall, and forming a second inorganic layer located above the first inorganic layer and covering the organic layer and the blocking wall;

wherein a cross section of the blocking wall is an inverted trapezoid structure.

According to an embodiment of the present invention, a material for forming the blocking wall is a photoresist material, and the step S30 comprises:

coating a photoresist layer on a surface of the first inorganic layer, and patternizing the photoresist layer to form the blocking wall by a photomask process.

According to an embodiment of the present invention, a material configured to make the blocking wall is polystyrene (PS).

According to an embodiment of the present invention, a cross section of the blocking wall is an inverted trapezoid structure.

According to an embodiment of the present invention, the OLED display panel further comprises a first inorganic layer and a second inorganic layer;

the first inorganic layer covers the OLED layer and extends to the non-displaying region of the substrate;

the blocking wall is formed on the first inorganic layer;

the organic layer is formed in the blocking space of the blocking wall; and

the second inorganic layer covers the organic layer and the blocking wall.

According to an embodiment of the present invention, the second inorganic layer covers a side of the blocking wall and contacts the first inorganic layer.

Advantages of the present invention are as follows. An OLED display panel and an OLED display panel manufacturing method are provided, and, by disposing the blocking wall over the substrate for blocking the organic solution from overflowing and spreading, increase the accuracy of the OLED display panel and enhance water oxygen resistance of the OLED display panel, which improves the quality of the OLED display panel.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may acquire other figures according to the appended figures without any creative effort.

FIG. 1 is a schematic structural view of an organic light-emitting diode (OLED) display panel of an embodiment of the present invention;

FIG. 2 is a schematic structural top view of the OLED display panel of the embedment of the present invention; and

FIG. 3 is a schematic flowchart of an OLED display panel manufacturing method of the present invention embodiment.

### DETAILED DESCRIPTION OF PREFERRED EMBODIMENTS

Each of the following embodiments is described with appending figures to illustrate specific embodiments of the present invention that are applicable. The terminologies of direction mentioned in the present invention, such as “upper”, “lower”, “front”, “rear”, “left”, “right”, “inner”, “outer”, “side surface”, etc., only refer to the directions of the appended figures. Therefore, the terminologies of direction are used for explanation and comprehension of the present invention, instead of limiting the present invention. In the figures, units with similar structures are marked with the same reference numerals.

The present invention aims at the issue that during formation an encapsulating portion of a conventional organic light-emitting diode (OLED) display panel, because an organic solution overflows and spreads when is leveled, the accuracy of the OLED display panel is reduced and the OLED display panel is less resistant to water oxygen. An OLED display panel and an OLED display panel manufacturing method are provided, the present invention can solve the above defects.

The present invention will be further described with accompanied figures and specific embodiments as follows.

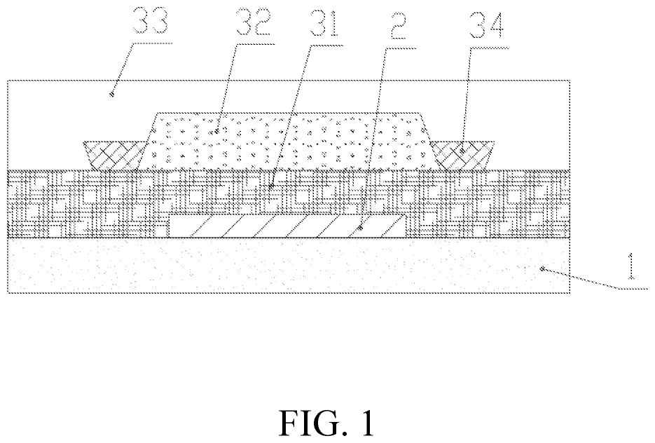

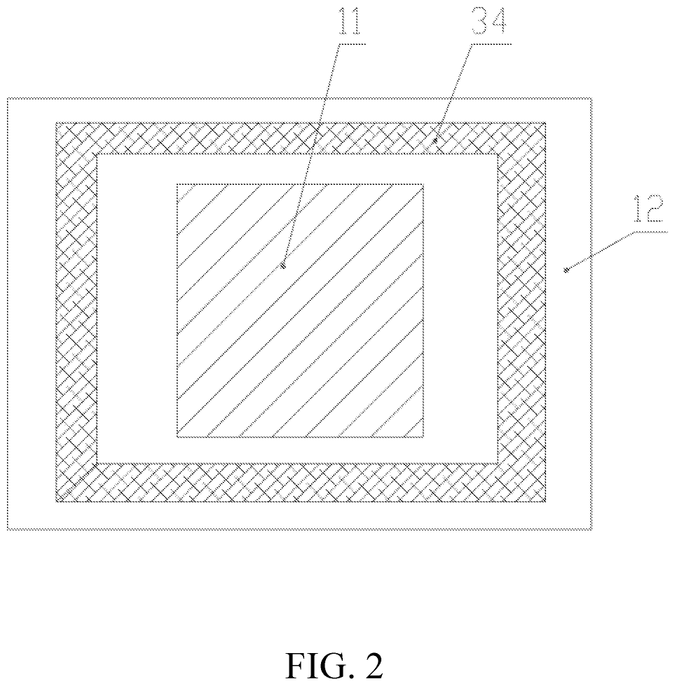

With reference to FIGS. 1 and 2, in an embodiment 1, the present invention provides an OLED display panel comprising a substrate 1 and an OLED layer 2.

The substrate 1, the substrate includes a displaying region 11, and a non-displaying region 12 disposed outside the displaying region.

In an embodiment, substrate 1 is an array substrate. A thin film transistor array is disposed in the displaying region 11 of the array substrate and is arranged evenly. A driver circuit and metal wires is disposed in the non-displaying region 12.

The OLED layer 2 is disposed in the displaying region 11 of the substrate 1.

In an embodiment, OLED layer 2 is composed of an anode, an organic layer and cathode. The organic layer includes a hole injection layer, a hole transport layer, an organic light-emitting layer, an electron transport layer and an electron injection layer. The organic light-emitting layer and the cathode are very sensitive to water oxygen and oxygen, and therefore, preventing invasion of water oxygen to the organic light-emitting layer of the OLED layer is extraordinarily important. Therefore, it is necessary to dispose an encapsulating portion in the OLED display panel for protecting the organic light-emitting layer and the cathode.

The encapsulating portion (including the first inorganic layer 31, the organic layer 32, the second inorganic layer 33 and the blocking wall 34) are disposed above the OLED layer 2, and the encapsulating portion includes an organic layer 32 and at least one blocking wall 34 surrounds the organic layer 32.

In an embodiment, the inorganic layer (including the first inorganic layer 31 and the second inorganic layer 33) is mainly configured to prevent invasion of water oxygen, organic layer 32 is mainly configured to cushion stress between the inorganic layers and cover micro particles of environment. However, because the organic layer 32 cannot block water oxygen, the inorganic layer needs to fully cover the organic layer 32.

In an embodiment, the organic layer 32 is located in the blocking space of the blocking wall.

In an embodiment, during formation of the organic layer 32, jet-printing, leveling and ultraviolet-curing processes are required. When the organic layer 32 is leveled, to match a film forming region of the first inorganic layer 31 and the second inorganic layer 33, it is necessary to level the organic solution on at a designated position. In such leveling process, the blocking wall 34 of the present invention effectively prevents the organic solution from overflowing and spreading during the leveling process, which further assures the accuracy of film formation of the organic layer 32.

In an embodiment, a cross section of the blocking wall 34 is an inverted trapezoid structure. The purpose of such disposing is that when the organic solution encounters the blocking wall 34 during the leveling, organic solution slowly contact an edge of the inverted trapezoid of the blocking wall 34. Because the edge of the blocking wall 34 is inclined upward, the organic solution flows inward back. The organic solution maintains a semi-spherical shape based relying on its own viscosity, which effectively prevents the organic layer 32 from overflowing.

In an embodiment, a material for forming the blocking wall is polystyrene (PS). Because of photosensitivity characteristic of polystyrene (PS), it is easy and convenient for the polystyrene (PS) to form an inverted trapezoid structure. It can be understood that the material for forming the blocking wall 34 of the present invention is not limited to polystyrene (PS).

In an embodiment, the encapsulating portion further includes a first inorganic layer 31 and a second inorganic layer 33.

In an embodiment, the first inorganic layer 31 covers the OLED layer 2 and extends to the non-displaying region 12 of the substrate.

The blocking wall 34 is formed on the first inorganic layer 31.

The organic layer 32 is formed in the blocking wall 34 [symbol] blocking space.

The second inorganic layer 33 covers the organic layer 32 and the blocking wall 34.

In an embodiment, the blocking wall 34 is disposed at an edge of the non-displaying region 12.

In an embodiment, a height of the blocking wall 34 is 1 microns to 2 microns.

In an embodiment, the second inorganic layer 32 covers a side of the blocking wall 34 and contacts the second inorganic layer 33.

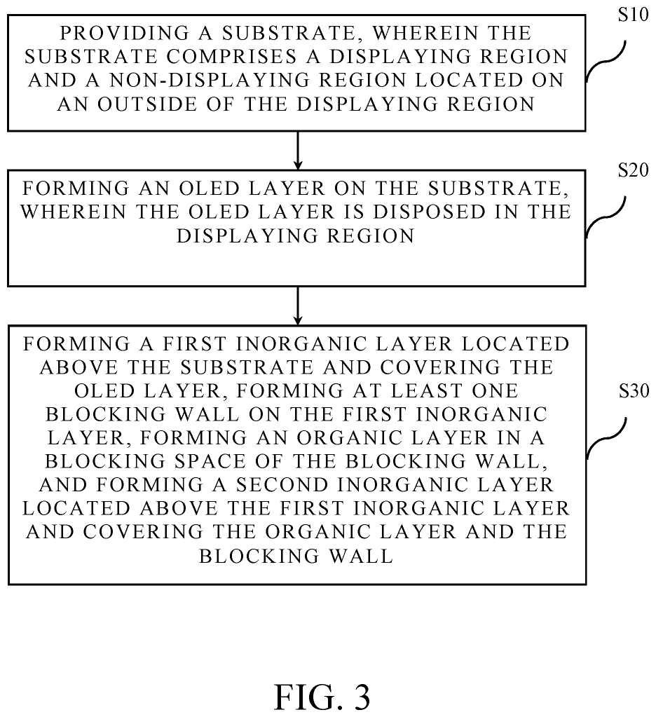

With reference to FIGS. 1, 2 and 3, according to another aspect of the present invention, an OLED display panel manufacturing method is also provided and includes step S10, step S20 and step S30.

The step S10 includes providing a substrate 1, wherein the substrate includes a displaying region 11 and a non-displaying region 12 located outside the displaying region 11.

The step S20 includes forming OLED layer 2 above the substrate 1, wherein the OLED layer 2 is disposed in the displaying region 12.

The step S30 includes forming a first inorganic layer 31 located above the substrate 1 and covering the OLED layer 2, forming at least one blocking wall 34 on the first inorganic layer 31, forming an organic layer 32 in a blocking space of the blocking wall 34, and forming a second inorganic layer 33 located above the first inorganic layer 31 and covering the organic layer 32 and the blocking wall 34;

Across section of the blocking wall 34 is an inverted trapezoid structure.

In an embodiment, a material for forming the blocking wall 34 is photoresist material, the step S30 includes:

A photoresist layer is coated on a surface of the first inorganic layer 31, a photomask process is employed to patternize the photoresist layer to form the blocking wall 34.

In an embodiment, a material for forming the blocking wall 34 is polystyrene (PS).

In an embodiment, the substrate 1 in the step S10 is an array substrate, a thin film transistor array is disposed in the of the displaying region 11 of the array substrate, and a driver circuit and metal wires and are disposed in the non-displaying region 12.

In an embodiment, the OLED layer 2 is composed of an anode, an organic layer and a cathode. The organic layer includes a hole injection layer, a hole transport layer, an organic light-emitting layer, an electron transport layer and an electron injection layer. The organic light-emitting layer and the cathode are very sensitive to water oxygen and oxygen, and therefore, preventing invasion of water oxygen to the organic light-emitting layer of the OLED layer is extraordinarily important. Therefore, it is necessary to dispose an encapsulating portion in the OLED display panel for protecting the organic light-emitting layer and the cathode.

The encapsulating portion (including the first inorganic layer 31, the organic layer 32, the second inorganic layer 33 and the blocking wall 34) are disposed above the OLED layer 2, and the encapsulating portion includes an organic layer 32 and at least one blocking wall 34 surrounds the organic layer 32.

The inorganic layer (including the first inorganic layer 31 and the second inorganic layer 33) is mainly configured to prevent invasion of water oxygen, organic layer 32 is mainly configured to cushion stress between the inorganic layers and cover micro particles of environment. However, because the organic layer 32 cannot block water oxygen, the inorganic layer needs to fully cover the organic layer 32.

In an embodiment, during formation of the organic layer 32, jet-printing, leveling and ultraviolet-curing processes are required. When the organic layer 32 is leveled, to match a film forming region of the first inorganic layer 31 and the second inorganic layer 33, it is necessary to level the organic solution on at a designated position. In such leveling process, the blocking wall 34 of the present invention effectively prevents the organic solution from overflowing and spreading during the leveling process, which further assures the accuracy of film formation of the organic layer 32.

In an embodiment, a cross section of the blocking wall 34 is an inverted trapezoid structure. The purpose of such disposing is that when the organic solution encounters the blocking wall 34 during the leveling, organic solution slowly contact an edge of the inverted trapezoid of the blocking wall 34. Because the edge of the blocking wall 34 is inclined upward, the organic solution flows inward back. The organic solution maintains a semi-spherical shape based relying on its own viscosity, which effectively prevents the organic layer 32 from overflowing.

In an embodiment, a material for forming the blocking wall 34 is polystyrene (PS). The purpose of the choice of the material is as follows. Because of photosensitivity characteristic of polystyrene (PS), it is easy and convenient for the polystyrene (PS) to form an inverted trapezoid structure. It can be understood that the material for forming the blocking wall 34 of the present invention is not limited to polystyrene (PS).

In an embodiment, the blocking wall 34 is disposed at an edge of the non-displaying region 12.

In an embodiment, the second inorganic layer 32 covers a side of the blocking wall 34 and contacts the second inorganic layer 33.

In an embodiment, a height of the blocking wall 34 is 2 microns to 4 microns.

Advantages of the present invention are as follows. An OLED display panel and an OLED display panel manufacturing method are provided, and, by disposing the blocking wall over the substrate for blocking the organic solution from overflowing and spreading, increase the accuracy of the OLED display panel and enhance water oxygen resistance of the OLED display panel, which improves the quality of the OLED display panel.

Although the preferred embodiments of the present invention have been disclosed as above, the aforementioned preferred embodiments are not used to limit the present invention. The person of ordinary skill in the art may make various changes and modifications without departing from the spirit and scope of the present invention. Therefore, the scope of protection of the present invention is defined by the scope of the claims.

What is claimed is:

1. An organic light-emitting diode (OLED) display panel, comprising:
a substrate comprising a displaying region and a non-displaying region located outside the displaying region;
an OLED layer disposed in the displaying region of the substrate;
an encapsulating portion disposed above the OLED layer, the encapsulating portion comprising an organic layer and at least one blocking wall surrounding the organic layer, wherein a height of the blocking wall is greater than 2 microns and is less than 4 microns; and
wherein the blocking wall is disposed in the non-displaying region of the substrate and is located at an edge of the non-displaying region, and the organic layer is located in a blocking space of the blocking wall.

2. The OLED display panel as claimed in claim 1, wherein a cross section of the blocking wall is an inverted trapezoid structure.

3. The OLED display panel as claimed in claim 2, wherein a material for forming the blocking wall comprises polystyrene (PS).

4. The OLED display panel as claimed in claim 1, wherein the encapsulating portion further comprises a first inorganic layer and a second inorganic layer;
the first inorganic layer covers the OLED layer and extends to the non-displaying region of the substrate;
the blocking wall is formed on the first inorganic layer;
the organic layer is formed in the blocking space of the blocking wall; and
the second inorganic layer covers the organic layer and the blocking wall.

5. The OLED display panel as claimed in claim 4, wherein the second inorganic layer covers a side of the blocking wall and contacts the first inorganic layer.

6. The OLED display panel as claimed in claim 1, wherein a thin film transistor array is disposed in the displaying region and is arranged evenly, and a driver circuit and metal wires are disposed in the non-displaying region.

7. The OLED display panel as claimed in claim 1 further comprising a polarizer and a cover plate disposed on the encapsulating portion.

8. An organic light-emitting diode (OLED) display panel, comprising:
a substrate comprising a displaying region and a non-displaying region located on an outside of the displaying region;
an OLED layer disposed in the displaying region of the substrate;
an encapsulating portion disposed above the OLED layer, and the encapsulating portion comprising an organic layer and at least one blocking wall surrounding the organic layer;
wherein the blocking wall is disposed in the non-displaying region of the substrate and is located at an edge of the non-displaying region, and the organic layer is located in a blocking space of the blocking wall.

9. The OLED display panel as claimed in claim 8, wherein a cross section of the blocking wall is an inverted trapezoid structure.

10. The OLED display panel as claimed in claim 9, wherein a material for forming the blocking wall comprises polystyrene (PS).

11. The OLED display panel as claimed in claim 8, wherein the encapsulating portion further comprises a first inorganic layer and a second inorganic layer;
the first inorganic layer covers the OLED layer and extends to the non-displaying region of the substrate;
the blocking wall is formed on the first inorganic layer;
the organic layer is formed in the blocking space of the blocking wall;
the second inorganic layer covers the organic layer and the blocking wall.

12. The OLED display panel as claimed in claim 11, wherein the second inorganic layer covers a side of the blocking wall and contacts the first inorganic layer.

13. The OLED display panel as claimed in claim 8, wherein a thin film transistor array is disposed in the displaying region and is arranged evenly, and a driver circuit and metal wires are disposed in the non-displaying region.

14. The OLED display panel as claimed in claim 8 further comprising a polarizer and a cover plate disposed on the encapsulating portion.

15. An organic light-emitting diode (OLED) display panel manufacturing method, comprising:
step S10, providing a substrate, wherein the substrate comprises a displaying region and a non-displaying region located on an outside of the displaying region;
step S20, forming an OLED layer on the substrate, wherein the OLED layer is disposed in the displaying region; and
step S30, forming a first inorganic layer located above the substrate and covering the OLED layer, forming at least one blocking wall on the first inorganic layer, forming an organic layer in a blocking space of the blocking wall, and forming a second inorganic layer located above the first inorganic layer and covering the organic layer and the blocking wall;
wherein a cross section of the blocking wall is an inverted trapezoid structure.

16. The OLED display panel manufacturing method as claimed in claim 15, wherein a material for forming the blocking wall is a photoresist material, and the step S30 comprises:
coating a photoresist layer on a surface of the first inorganic layer, and patternizing the photoresist layer to form the blocking wall by a photomask process.

17. The OLED display panel manufacturing method as claimed in claim 15, wherein a material configured to make the blocking wall is polystyrene (PS).

18. The OLED display panel manufacturing method as claimed in claim 15, wherein a cross section of the blocking wall is an inverted trapezoid structure.

19. The OLED display panel manufacturing method as claimed in claim 15, wherein the OLED display panel further comprises a first inorganic layer and a second inorganic layer;
the first inorganic layer covers the OLED layer and extends to the non-displaying region of the substrate;
the blocking wall is formed on the first inorganic layer;
the organic layer is formed in the blocking space of the blocking wall; and
the second inorganic layer covers the organic layer and the blocking wall.

20. The OLED display panel manufacturing method as claimed in claim 19, wherein the second inorganic layer covers a side of the blocking wall and contacts the first inorganic layer.
